(19) United States
(12) Patent Application Publication
(10) Pub. No.: US 2009/0295455 A1
(43) Pub. Date: Dec. 3, 2009

(54) SYSTEM FOR CONTROLLING AN ELECTRONIC DRIVER FOR A NEBULISER

(76) Inventor: Martin Scott Goodchild, Cambridgeshire (GB)

Correspondence Address: JOHN P. DE LUCA, 17420 RYEFIELD CT., DICKERSON, MD, 20842, US

(21) Appl. No.: 11/915,592

(22) PCT Filed: May 30, 2006
(86) PCT No.: PCT/EP2006/062711

§ 371 Date: Jul. 28, 2009

(30) Foreign Application Priority Data
Jun. 6, 2005 (EP) 05253463.3

(51) Int. Cl. H03K 17/687

(52) U.S. Cl. 327/424

(57) ABSTRACT

A system for controlling an electronic driver for a nebuliser or aerosol, the system comprising: an H-bridge driver for connection around a membrane to be driven; a voltage source for applying a voltage to the H-bridge driver; a feedback loop from the H-bridge to a phase shift oscillator, the output of which enters the H-bridge driver; wherein the H-bridge driver includes at least one sense resistor for detecting the phase angle between the applied voltage to the H-bridge driver and the applied current.

This invention relates to a system for controlling an electronic driver, typically for use with a nebulizer or aerosol or other like device.

When operating electronic drivers, it is important that the driver, typically including a piezoelectric device, is operated at the optimum frequency of a series resonance where the admittance is at a maximum. Operating a piezoelectric device at the optimum frequency achieves maximum mechanical displacement and is the optimum drive for droplet ejection and maximum power efficiency. In order to achieve droplet ejection at frequencies near to the optimum frequency, it is preferable that the device is operated at frequencies where the admittance of the piezoelectric device is within 1-3 dB of the device=s maximum admittance at series resonance. However, operating at these non-optimum frequencies requires an increase in the applied voltage to achieve comparable mechanical displacement.

In order to achieve frequency selection to operate close to the optimum drive frequency, it is known to have electrical feedback using three possible arrangements. Firstly, it is possible to use a constant drive voltage and detect the maximum current, alternatively a constant drive current can be applied and the minimum voltage detected or thirdly a constant drive voltage can be applied and the phase angle detected between the applied voltage and the current using a current sense resistor.

Such a device is described in U.S. Pat. No. 6,539,937 in which an alternating voltage causes a piezoelectric element to contract from the normal condition to a radially decreased condition and then return to the normal condition. In this arrangement, the applied voltage will be zero when the piezoelectric element is in the flat or normal condition and that the applied voltage, V, will be something other than zero when the piezoelectric element is in the radially decreased condition.

In U.S. Pat. No. 6,539,937, an electronic piezoelectric device driver is provided to use as a feedback signal to generate an oscillating voltage source to operate the device at a frequency that is very close to the frequency necessary to obtain the maximum of mechanical displacement. The feedback signal is obtained by either a strain gauge mounted in the device or by an electrical measurement.

According to the present invention, there is provided a system for controlling electronic driver for a nebuliser or aerosol, the system comprising:

an H-bridge driver for connection around a membrane to be driven;

a voltage source for applying a voltage to the H-bridge driver;

a feedback loop from the H-bridge to a phase shift oscillator, the output of which enters the H-bridge driver;

wherein the H-bridge driver includes at least one sense resistor for detecting the phase angle between the applied voltage and the H-bridge driver and the applied current.

In the present invention, it is preferable that the system controls a piezoelectric device. One way to consider an H-bridge driver is as two push-pull drivers operating in anti-phase with the piezoelectric device connected between their outputs.

During operation, it is preferable that, in the flat or normal condition, the applied voltage will be zero only when the driver circuitry has been switched off. The switching of the H-bridge is such that the piezoelectric device can alternate between radially decreased and radially increased conditions when the applied voltage is something other than zero. Thus, in order to obtain the same maximum displacement as a push-pull driver switching zero volts and V volts across the device, an H-bridge driver will be switching +V/2 volts and BV/2 volts across the device, therefore only needing V/2 volts to be supplied to the H-bridge driver circuitry.

A key advantage of a H-bridge driver is that a lower voltage supply (V/2) is necessary and this can reduce the demand placed on any DC/DC voltage up converter and means that the H-bridge driver can be employed in low voltage battery applications. A potential downside of the H-bridge driver is that there is an increased amount of circuitry, however this will have a minimum impact in any ASIC based design where the additional circuitry will reside in the ASIC.

Self-tuning electronics such as the present invention are designed to take advantage of the changes in electrical impedance and phase that occur when an oscillating voltage is applied to a piezoelectric device at a frequency that will achieve mechanical resonant vibration. Typically, self-tuning electronics take advantage of a fast changing phase response at resonance. High order resonant modes are selected by tuning the self-tuning electronics to operate within a band of frequencies that includes the desired resonant mode.

Preferably, the system of the present invention uses a series inductor for tuning with the parallel capacitance of the device. This series inductance performs several functions: firstly, phase shift, secondly, voltage gain, and electrical efficiency improvement by recovering the energy stored in the parallel capacitance of the device.

To enable a self-tuning system to operate, a feedback signal is required. In order to reduce the complexity and cost of the system with a piezoelectric device, a current sensing resistor is used in series with the piezoelectric device. Impedance and phase information can be obtained with a current sense resistor without the need for a third sense electrode on the piezoelectric device. Such a system is a two wire self-tuning electronics driver.

The system preferably comprises an H-bridge driver having two sense resistors, one in each half of the bridge. The system preferably further comprises a means for self-starting the oscillator as this overcomes any threshold necessary to enable the switching output H-bridge drive and results in a free running alternating oscillator output even when the piezoelectric device is not connected. Once the piezoelectric device has been connected, then the alternating output signal will then be self-tuned to the resonance of that device.

The feedback loop preferably contains one of the following: a differential amplifier, a phase-locked loop device, or a phase shift oscillator or a microcontroller. The H-bridge preferably also spans an inductor in series with the membrane to produce a phase shift between the applied voltage and applied current to tune out any parallel plate capacitance and improve the electrical efficiency of the driver.

With a feedback signal, two options exist for generating an oscillating drive signal: firstly an amplifier where the gain is greater than one and the feedback signal provides a 360° phase shift (positive feedback) for oscillation to occur. Secondly, a phase-locked loop (PLL) or microcontroller, a more complicated system where the phase of the feedback signal is compared with an internally generated reference frequency signal, phase locking is achieved when the phase angle between the two signals has been minimised by adjusting the reference frequency, typically with a voltage control oscillator with a PLL integrated circuit. In both cases it is likely that some form of phase-shifting circuitry will be required.

Recent electronic driver designs have aimed at removing the need for a transformer so that the physically smaller electronics can be fabricated, largely within a ASIC, but without a transformer. In such a design, the voltage gain is achieved with a DC/DC converter, an H-bridge driver stage and a series tuning inductor. With a H-bridge circuit, the piezoelectric device can see a maximum applied voltage of V for each half cycle, however the switching of the H-bridge reverses the plurality of the applied voltage for each half cycle. This results in peak-to-peak voltage of 2V being applied to the piezo device. The net benefit to this approach is that to achieve a peak-to-peak of only V across the piezo device, the DC/DC converter need only provide V/2 to the H-bridge driver circuitry. The reduced size and specification for the DC/DC converter allows a low voltage battery supply to be used, typically less than two volts.

With an H-bridge circuit, the current sense feedback signal is derived from at least one, but preferably two, sense resistors, one for each half of the bridge. The full feedback signal can be recreated using a differential amplifier. When using only a single sense resistor, phase information can still be obtained from the system.

In the present invention, when a feedback amplifier is used, the amplifier is enhanced to operate in a differential mode, thereby recreating the full feedback signal as if it had been obtained from a single resistor in series with a piezoelectric device that is being driven by a push-pull driver. With the feedback signal, the frequency can be tuned within a phase shift oscillator.

A further benefit of an H-bridge driver is that the piezoelectric element which is being driven is not mechanically stressed to the same extent as in a push-pull driver when achieving the same mechanical displacement. With the H-bridge driver, the piezoelectric element is radially increased and radially decreased about a normal or flat condition, whereas with a push pull driver, as described in U.S. Pat. No. 6,539,937, alternates the piezoelectric element between a flat condition and a radially decreased condition.

One example of the present invention will now be described with reference to the accompanying drawings, in which:

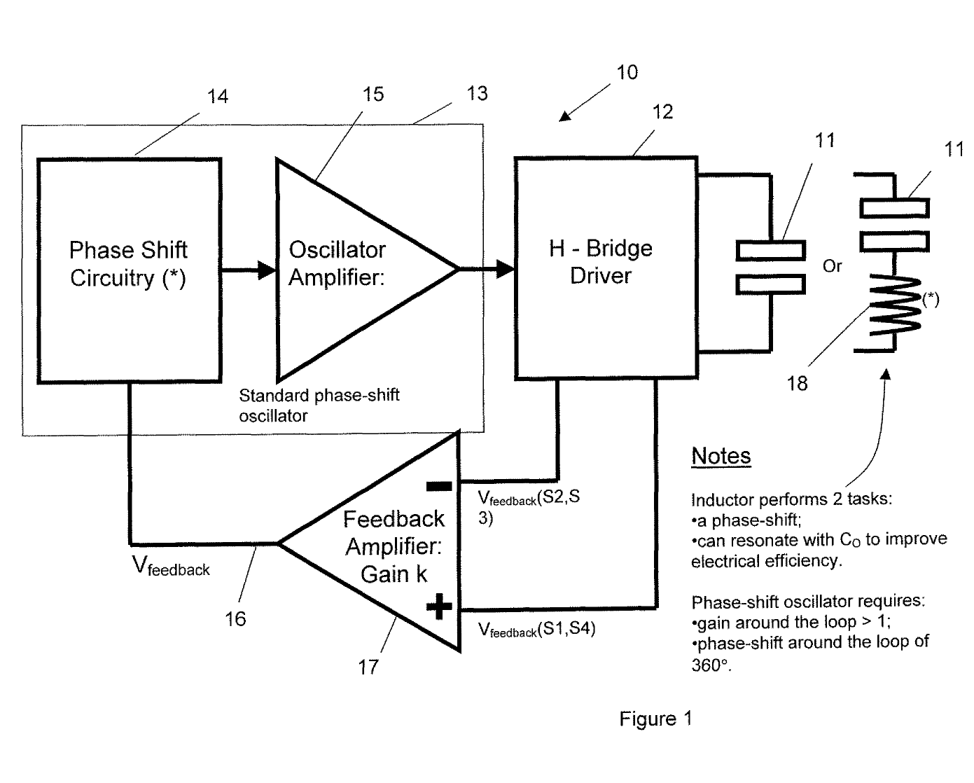

FIG. 1 is a block diagram showing control system of the present invention;

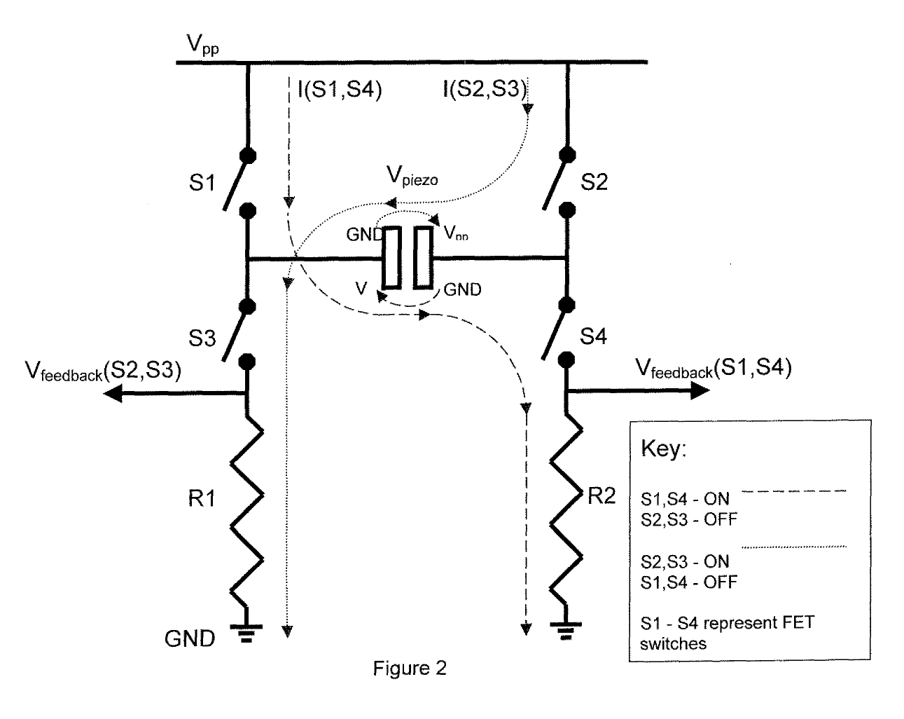

FIG. 2 is one example of the H-bridge driver circuit from FIG. 1;

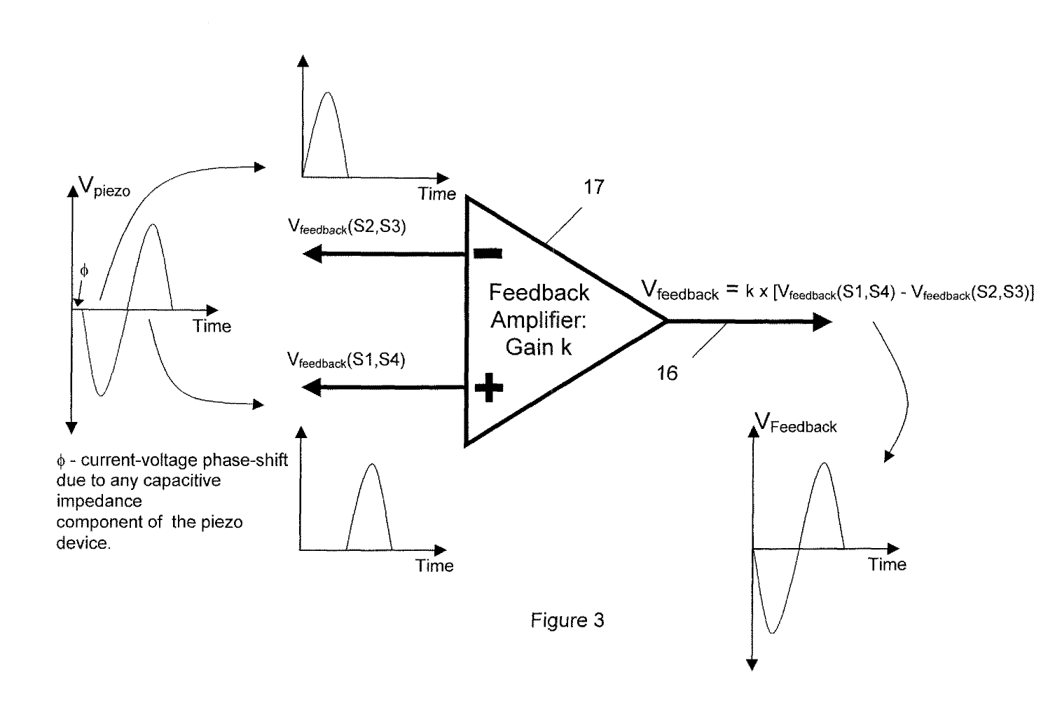

FIG. 3 shows details of the feedback amplifier portion of the circuit of FIG. 1; and

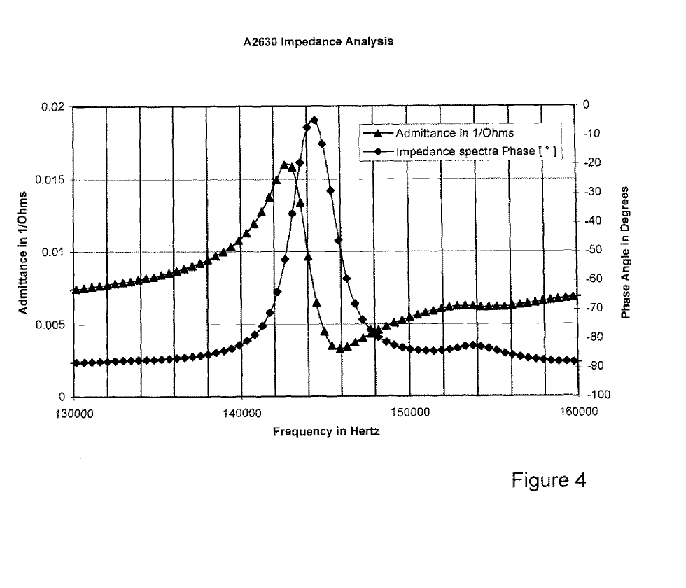

FIG. 4 shows typical electrical characteristic of a piezoelectric device.

In FIG. 1, a system 10 for controlling a piezoelectric element (not shown, but represented by the capacitor 11) is provided. The capacitance (piezoelectric element) 11 is driven by an H-bridge driver 12, the input of which is provided by a standard phase shift oscillator 13, including phase shift circuitry 14 and an oscillator amplifier 15. A feedback loop 16 leads from the H-bridge driver to the phase shift circuitry and includes a feedback amplifier 17. An inductor 18 can also be provided in series with the capacitance 11 (piezoelectric element) in order to provide a phase shift and it can resonate with the capacitor to improve electrical efficiency.

The phase shift oscillator requires a gain around the feedback loop of greater than 1 and a phase shift around the loop of 360°.

FIG. 2 shows the H-bridge driver 12 in greater detail. The H-bridge spans the capacitance 11 providing a left and right half of the bridge (as seen in FIG. 2). Each half of the bridge is provided with a current sensor resistor R1, R2. Switches S1 to S4 are provided on either side of the capacitor such that, in operation, current is caused to flow through the capacitor in either direction by closing either switches S2 and S3 or, alternatively, S1 and S4. This provides an effective alternating voltage across, and an alternating current through, the capacitor 11. A feedback voltage is taken of each side of the bridge before the respective sensor resistor R1, R2. Preferably, switches S1 to S4 are Field Effect Transistor switches (FET switches) or Bipolar Junction Transistor switches (BJT switches).

FIG. 3 illustrates the feedback amplifier circuit and how the feedback voltage is recreated from each half of the bridge circuit to create a full wave feedback signal. If only one sensor resistor R1 or R2 is used in the H-bridge, then only one half of the feedback voltage signal is created. This approach could be utilised to provide the phase information necessary for a phase shift oscillator but there could be increased oscillator instability due to the asymmetry of the feedback signal.

FIG. 4 illustrates a typical measurement from a typical piezoelectric device shown in FIGS. 1 and 2. From this Figure it can clearly be seen that the admittance maximum occurs across a relatively linear section of the phase response, also roughly corresponding to being within one dB of the maximum frequency. Employing a linear transfer function such as the phase response as described above instead of a function with a turning point, can simplify the design of oscillator. By employing an appropriate phase shift at the series resonance, it is possible for a phase shift resonator to provide a reliable and stable output at a frequency that is very close to the admittance maximum.

1. A system for controlling an electronic driver for a nebuliser or aerosol, the system comprising:
an H-bridge driver for connection around a membrane to be driven;
a voltage source for applying a voltage to the H-bridge driver;
a feedback loop from the H-bridge to a phase shift oscillator, the output of which enters the H-bridge driver;
wherein the H-bridge driver includes at least one sense resistor for detecting the phase angle between the applied voltage to the H-bridge driver and the applied current.

2. A system according to claim 1, wherein the H-bridge driver includes two sense resistors, one on each half of the bridge.

3. A system according to claim 1, further comprising a means for self-starting the oscillator.

4. A system according to claim 1, wherein the feedback loop contains one of the following: a differential amplifier, a phase-locked loop or a microcontroller.

5. A system according claim 1, wherein the H-bridge also spans an inductor in series with the membrane to produce a phase shift between the applied voltage and applied current and to tune out any parallel plate capacitance.

6. A system according to claim 1, wherein the voltage source includes a DC/DC voltage converter.
